(19) United States
(12) Patent Application Publication
(10) Pub. No.: US 2025/0380619 A1
(43) Pub. Date: Dec. 11, 2025

(54) ELECTRONIC CIRCUIT AND COMPUTING DEVICE

(71) Applicant: KABUSHIKI KAISHA TOSHIBA, Tokyo (JP)

(72) Inventors: Noritsugu SHIOKAWA, Yokohama (JP); Tamio KAWAGUCHI, Yokohama (JP)

(73) Assignee: KABUSHIKI KAISHA TOSHIBA, Tokyo (JP)

(21) Appl. No.: 19/032,540

(22) Filed: Jan. 21, 2025

(30) Foreign Application Priority Data
Jun. 6, 2024 (JP) 2024-092183

(51) Int. Cl. H10N 60/81; H10N 60/12

(52) U.S. Cl. CPC H10N 60/815; H10N 60/12

(57) ABSTRACT

According to one embodiment, an electronic circuit includes a circuit component, and a conductive component. The circuit component includes a dielectric substrate and a circuit member. The circuit component includes an outer edge and an inner region inside the outer edge on a first plane crossing a first direction from the dielectric substrate to the circuit member. The outer edge includes first and second partial regions. The conductive component includes an inner conductive region, a first conductive region, and a second conductive region. A position of the inner conductive region in the second direction is between a position of the first conductive region in the second direction and a position of the second conductive region in the second direction. A first gap is between the first conductive region and the first partial region, and a second gap is between the second conductive region and the second partial region.

### CROSS-REFERENCE TO RELATED APPLICATIONS

This application is based upon and claims the benefit of priority from Japanese Patent Application No. 2024-092183, filed on Jun. 6, 2024; the entire contents of which are incorporated herein by reference.

### FIELD

Embodiments described herein relate generally to an electronic circuit and a computing device.

### BACKGROUND

For example, electronic circuits are applied to computing devices such as quantum computers. Stable characteristics are desired in electronic circuits.

### BRIEF DESCRIPTION OF THE DRAWINGS

FIG. 1 is a schematic perspective view illustrating an electronic circuit according to the first embodiment;

FIGS. 2A and 2B are schematic cross-sectional views illustrating the electronic circuit according to the first embodiment;

FIG. 3 is a schematic plan view illustrating the electronic circuit according to the first embodiment;

FIG. 4 is a graph illustrating the characteristics of the electronic circuit;

FIGS. 5A to 5C are schematic views illustrating a part of the electronic circuit according to the first embodiment;

FIG. 6 is a schematic plan view illustrating an electronic circuit according to the first embodiment;

FIG. 7 is a schematic perspective view illustrating an electronic circuit according to the first embodiment;

FIGS. 8A and 8B are schematic cross-sectional views illustrating the electronic circuit according to the first embodiment;

FIG. 9 is a schematic plan view illustrating the electronic circuit according to the first embodiment;

FIG. 10 is a schematic perspective view illustrating an electronic circuit according to the first embodiment;

FIGS. 11A and 11B are schematic cross-sectional views illustrating an electronic circuit according to the first embodiment;

FIG. 12 is a schematic perspective view illustrating an electronic circuit according to the first embodiment;

FIGS. 13A and 13B are schematic cross-sectional views illustrating the electronic circuit according to the first embodiment; and

FIG. 14 is a schematic perspective view illustrating a computing device according to a second embodiment.

### DETAILED DESCRIPTION

According to one embodiment, an electronic circuit includes a circuit component, and a conductive component. The circuit component includes a dielectric substrate and a circuit member. The circuit component includes an outer edge and an inner region inside the outer edge on a first plane crossing a first direction from the dielectric substrate to the circuit member. The outer edge includes a first partial region and a second partial region. The inner region is between the first partial region and the second partial region in a second direction crossing the first direction along the first plane. The conductive component includes an inner conductive region, a first conductive region, and a second conductive region. A position of the inner conductive region in the second direction is between a position of the first conductive region in the second direction and a position of the second conductive region in the second direction. A direction from the inner conductive region to the inner region is along the first direction. A first gap is between the first conductive region and the first partial region, and a second gap is between the second conductive region and the second partial region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

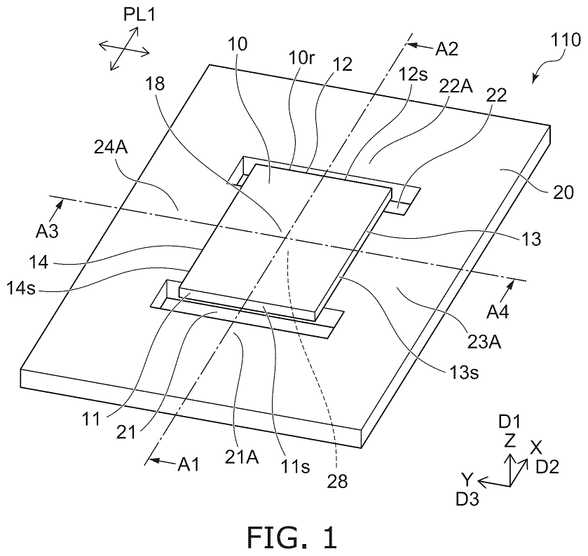

FIG. 1 is a schematic perspective view illustrating an electronic circuit according to the first embodiment.

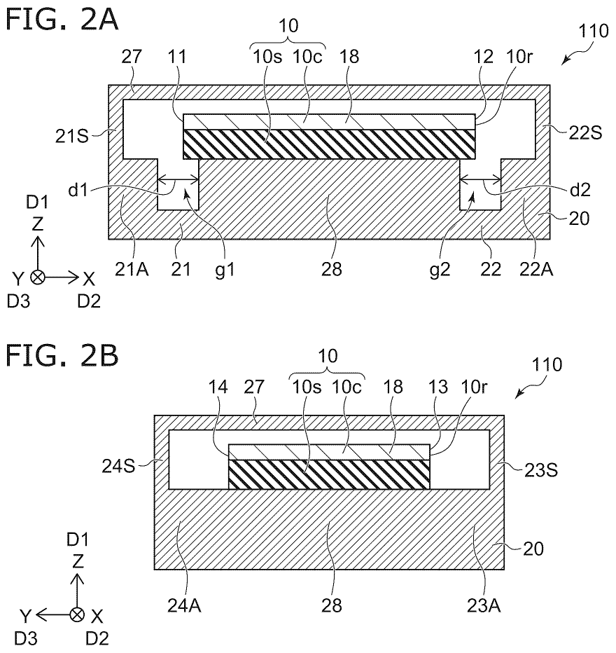

FIGS. 2A and 2B are schematic cross-sectional views illustrating the electronic circuit according to the first embodiment.

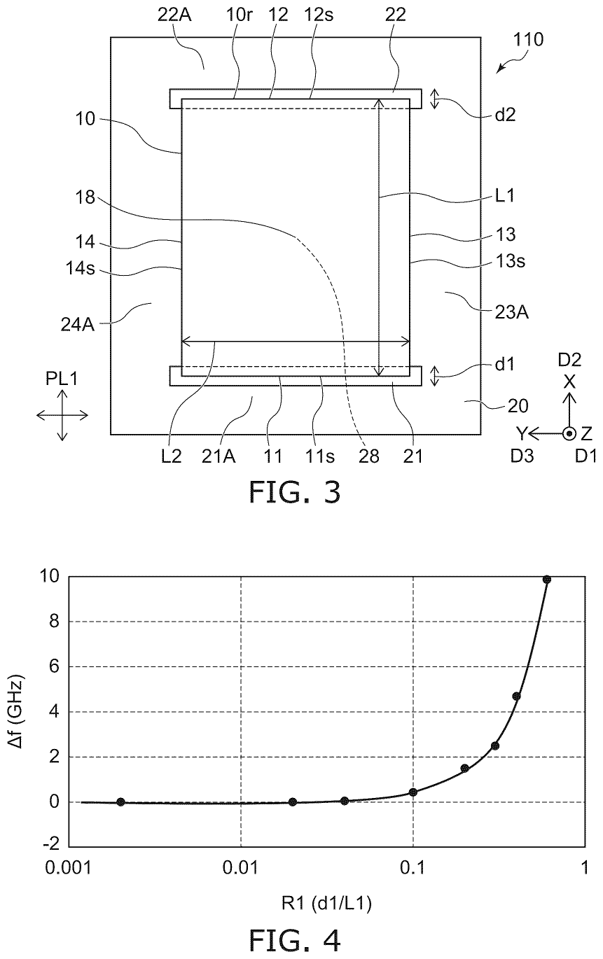

FIG. 3 is a schematic plan view illustrating the electronic circuit according to the first embodiment.

FIG. 2A is a cross-sectional view taken along the line A1-A2 in FIG. 1. FIG. 2B is a cross-sectional view taken along the line A3-A4 in FIG. 1. As shown in FIG. 1, an electronic circuit 110 according to an embodiment includes a circuit component 10 and a conductive component 20.

As shown in FIGS. 2A and 2B, the circuit component 10 includes a dielectric substrate 10s and a circuit member 10c. The circuit member 10c includes, for example, a high-frequency circuit. The high-frequency circuit may include, for example, a quantum bit. The quantum bit may include, for example, a Josephson junction. In one example, the circuit component 10 is a high-frequency chip.

A first direction D1 from the dielectric substrate 10s to the circuit member 10c is defined as a Z-axis direction. One direction perpendicular to the Z-axis direction is defined as an X-axis direction. A direction perpendicular to the Z-axis and X-axis directions is defined as a Y-axis direction.

As shown in FIG. 1, the circuit component 10 includes an outer edge 10r and an inner region 18. The inner region 18 is inside the outer edge 10r on a first plane PL1 crossing the first direction D1 from the dielectric substrate 10s to the circuit member 10c. The first plane PL1 is, for example, the X-Y plane.

The outer edge 10r includes a first partial region 11 and a second partial region 12. In a second direction D2, the inner region 18 is between the first partial region 11 and the second partial region 12. The second direction D2 is along the first plane PL1 and crosses the first direction D1. In one example, the second direction D2 may be along the X-axis direction.

As shown in FIGS. 1 and 3, in this example, the outer edge 10r is substantially rectangular. In the embodiment, the shape of the outer edge 10r is arbitrary. In this example, the outer edge 10r includes a first side 11s and a second side 12s. The first partial region 11 may include at least a part of the first side 11s of the outer edge 10r. The second partial region 12 may include at least a part of the second side 12s of the outer edge 10r.

For example, at least a part of the first partial region 11 may be along a third direction D3. At least a part of the second partial region 12 may be along the third direction D3. The third direction D3 is along the first plane PL1 and crosses the second direction D2. For example, the third direction D3 may be along the Y-axis direction. The third direction D3 may be inclined with respect to the second direction D2.

For example, the outer edge 10r may further include a third partial region 13 and a fourth partial region 14. The third direction D3 from the third partial region 13 to the fourth partial region 14 is along the first plane PL1 and crosses the second direction D2. The outer edge 10r may include a third side 13s and a fourth side 14s. The third partial region 13 may include at least a part of the third side 13s of the outer edge 10r. The fourth partial region 14 may include at least a part of the fourth side 14s of the outer edge 10r.

As shown in FIG. 1, the conductive component 20 includes an inner conductive region 28, a first conductive region 21, and a second conductive region 22. As shown in FIG. 2A, a position of the inner conductive region 28 in the second direction D2 is between a position of the first conductive region 21 in the second direction D2 and a position of the second conductive region 22 in the second direction D2.

A direction from the inner conductive region 28 to the inner region 18 is along the first direction D1. For example, the inner region 18 overlaps the inner conductive region 28 in the first direction D1. For example, the inner region 18 is fixed to the inner conductive region 28. For example, the inner conductive region 28 supports the inner region 18. For example, the inner conductive region 28 contacts the inner region 18. For example, the inner conductive region 28 may contact the dielectric substrate 10s included in the inner region 18. For example, the inner conductive region 28 may contact the inner region 18 directly or indirectly. When the inner conductive region 28 contacts the inner region 18 indirectly, another member may be provided between the inner conductive region 28 and the inner region 18, and the other member may contact the inner conductive region 28 and the inner region 18. The inner conductive region 28 is thermally connected to the inner region 18. For example, the relative positional relationship between the inner region 18 and the inner conductive region 28 in the first plane PL1 is fixed.

As shown in FIG. 2A, a first gap g1 exists between the first conductive region 21 and the first partial region 11. A second gap g2 exists between the second conductive region 22 and the second partial region 12.

With such a configuration, for example, the influence of spurious modes caused by the circuit component 10 and the conductive component (such as conductive component 20) present in its periphery can be suppressed. For example, the chip mode frequency can be increased. Furthermore, by fixing the inner region 18 of the circuit component 10 to the inner conductive region 28 of the conductive component 20, heat from the circuit component 10 is efficiently transferred to the conductive component 20. High thermal conductance is obtained. Effective heat dissipation is obtained. Thereby, for example, noise and the like is suppressed. More stable operation is obtained. For example, losses can be reduced. For example, high efficiency is obtained. According to the embodiment, an electronic circuit capable of obtaining stable characteristics can be provided.

As shown in FIG. 2A, the inner conductive region 28 protrudes toward the circuit component 10 with respect to the first conductive region 21 and the second conductive region 22. The first conductive region 21 and the second conductive region 22 recede with respect to the inner conductive region 28.

As shown in FIGS. 1 and 2A, the conductive component 20 may further include a first outer conductive region 21A and a second outer conductive region 22A. The position of the first conductive region 21 in the second direction D2 is between the position of the inner conductive region 28 in the second direction D2 and a position of the first outer conductive region 21A in the second direction D2. The position of the second conductive region 22 in the second direction D2 is between the position of the inner conductive region 28 in the second direction D2 and a position of the second outer conductive region 22A in the second direction D2. The first gap g1 exists between the inner conductive region 28 and the first outer conductive region 21A. The second gap g2 exists between the inner conductive region 28 and the second outer conductive region 22A.

For example, the first conductive region 21 and the second conductive region 22 correspond to a recess. For example, the first conductive region 21 and the second conductive region 22 may be a hole or a groove. The inner conductive region 28 corresponds to, for example, a protrusion.

As shown in FIG. 2A, the conductive component 20 may further include an opposing conductive region 27. The circuit component 10 is between the inner conductive region 28 and the opposing conductive region 27 in the first direction D1. As shown in FIG. 2A, the conductive component 20 may further include a first side portion 21S and a second side portion 22S. The circuit component 10 is, for example, between the first side portion 21S and the second side portion 22S in the second direction D2. In FIG. 1, the opposing conductive region 27 and the plurality of side portions are omitted.

The first conductive region 21 may be continuous with the inner conductive region 28. The first outer conductive region 21A may be continuous with the first conductive region 21. The first side portion 21S may be continuous with the first outer conductive region 21A. The opposing conductive region 27 may be continuous with the first side portion 21S.

The second conductive region 22 may be continuous with the inner conductive region 28. The second outer conductive region 22A may be continuous with the second conductive region 22. The second side portion 22S may be continuous with the second outer conductive region 22A. The opposing conductive region 27 may be continuous with the second side portion 22S.

As shown in FIGS. 1 and 2B, the conductive component 20 may further include a third outer conductive region 23A and a fourth outer conductive region 24A. A position of the inner conductive region 28 in the third direction D3 is between a position of the third outer conductive region 23A in the third direction D3 and a position of the fourth outer conductive region 24A in the third direction D3.

As shown in FIG. 2B, the conductive component 20 may further include a third side portion 23S and a fourth side portion 24S. The circuit component 10 is, for example, between the third side portion 23S and the fourth side portion 24S in the third direction D3.

The third outer conductive region 23A may be continuous with the inner conductive region 28. The third side portion 23S may be continuous with the third outer conductive region 23A. The opposing conductive region 27 may be continuous with the third side portion 23S.

The fourth outer conductive region 24A may be contiguous with the inner conductive region 28. The fourth side portion 24S may be contiguous with the fourth outer conductive region 24A. The opposing conductive region 27 may be contiguous with the fourth side portion 24S.

For example, a first reference example can be conceivable in which the first conductive region 21 and second conductive region 22 mentioned above are not provided. In the first reference example, the entire circuit component 10 is supported by the inner conductive region 28 of the conductive component 20. In the first reference example, a recess (such as a groove or hole) formed by the first conductive region 21 and the second conductive region 22 is not provided. In such a first reference example, adverse effects due to high-frequency spurious mode signals are likely to occur. For example, the target frequency in the circuit component 10 and the frequency of the spurious mode signal are close to each other, making it difficult for the circuit component 10 to perform the intended operation.

For example, a second reference example is conceivable in which the conductive component 20 does not include the inner conductive region 28. In the second reference example, the end including the outer edge 10r of the circuit component 10 is supported by the outer conductive region. The end is, for example, four corners. The outer conductive regions include the first outer conductive region 21A, the second outer conductive region 22A, the third outer conductive region 23A, and the fourth outer conductive region 24A. In the second reference example, a gap is provided under the inner region 18 of the circuit component 10. In such a second reference example, heat dissipation is insufficient. For example, in the case where the circuit member 10c includes a quantum bit or the like, an adverse effect on maintaining a low temperature in the circuit member 10c will arise. For example, noise is easily generated in the circuit member 10c, making it difficult to obtain stable operation.

In contrast, in the embodiment, the effects of spurious modes can be suppressed. High heat dissipation is achieved, and low temperatures can be easily maintained. Noise is suppressed, and stable operation can be achieved.

For example, in the first reference example, the frequency of the spurious mode is 10.0 GHZ. In the second reference example, the frequency of the spurious mode is 12.1 GHZ. In the embodiment, the frequency of the spurious mode is 12.1 GHZ.

In practice, heat in the circuit component 10 tends to concentrate in the inner region 18. For example, the temperature in the inner region 18 tends to be higher than the temperature in the region including the outer edge 10r. In the embodiment, the heat in the inner region 18 can be efficiently transferred to the inner conductive region 28. Effective heat dissipation is obtained.

A gap may be provided between the circuit component 10 and the opposing conductive region 27. The circuit component 10 is provided in the space inside the conductive component 20. This space may be depressurized.

As shown in FIG. 3, a length of the circuit component 10 in the second direction D2 is defined as a first length L1. A length of the circuit component 10 in the “crossing direction” is defined as a second length L2. The “crossing direction” is along the first plane PL1 and crosses the second direction D2. The crossing direction may be, for example, the third direction D3. The crossing direction may be the Y-axis direction.

In this example, the first length L1 is longer than the second length L2. In this example, the planar shape of the circuit component 10 is substantially rectangular. The first length L1 is the length of the circuit component 10 in the major axis direction.

In such a case, the second direction D2 from the first conductive region 21 to the second conductive region 22 may be along the longitudinal direction of the circuit component 10. For example, adverse effects due to spurious modes are likely to occur at the ends in the longitudinal direction. By the second direction D2 from the first conductive region 21 to the second conductive region 22 be along the longitudinal direction of the circuit component 10, adverse effects due to spurious modes can be effectively suppressed. For example, concentration of the electric field occurring at the ends in the longitudinal direction is effectively suppressed. In the embodiment, the first length L1 may be equal to or less than the second length L2.

As shown in FIGS. 3 and 2A, a distance in the second direction D2 between the inner conductive region 28 and the first outer conductive region 21A is defined as a first distance d1. A distance in the second direction D2 between the inner conductive region 28 and the second outer conductive region 22A is defined as the second distance d2. The first distance d1 corresponds to the width of the recess based on the first conductive region 21. The second distance d2 corresponds to the width of the recess based on the second conductive region 22.

FIG. 4 is a graph illustrating the characteristics of the electronic circuit.

FIG. 4 illustrates the results of a simulation regarding the characteristics of the electronic circuit 110. The horizontal axis of FIG. 4 corresponds to a first ratio R1. The first ratio R1 is the ratio (d1/L1) of the first distance d1 to the first length L1. The vertical axis of FIG. 4 is a frequency shift amount Δf of the spurious mode. It is preferable that the shift amount Δf is large. Thereby, the difference between the frequency of the high-frequency circuit (e.g., quantum bit) in the circuit member 10c and the frequency of the spurious mode is increased and the effects of noise and the like are suppressed. In this example, the second distance d2 is the same as the first distance d1.

As shown in FIG. 4, as the first ratio R1 increases, the shift amount Δf increases. For example, when the first ratio R1 is 0.1 or more, the shift amount Δf clearly increases. The chip mode frequency can be effectively increased. In the embodiment, it is preferable that the ratio of the first distance d1 to the first length L1 (first ratio R1) is 0.1 or more. The influence of spurious modes can be effectively suppressed.

For example, if the first ratio R1 is excessively high, the area of the inner region 18 becomes excessively small. Thereby, it becomes difficult to obtain sufficient heat dissipation. Practically, the first ratio R1 may be 0.3 or less. In the embodiment, the ratio of the first distance d1 to the first length L1 may be 0.3 or less. High heat dissipation is obtained. In the embodiment, the first distance d1 may be the same as the second distance d2, or may be different.

As shown in FIG. 3, in the example of the electronic circuit 110, the first conductive region 21 overlaps the entire first partial region 11 in the first direction D1. The second conductive region 22 overlaps the entire second partial region 12 in the first direction D1.

In the embodiment, the first conductive region 21 may overlap a part of the first partial region 11 in the first direction D1. The second conductive region 22 may overlap a part of the second partial region 12 in the first direction D1.

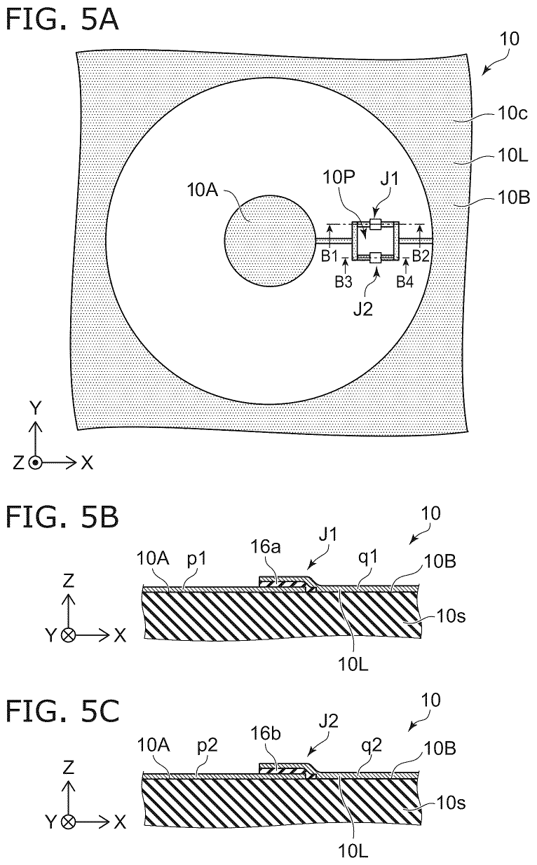

FIGS. 5A to 5C are schematic views illustrating a part of the electronic circuit according to the first embodiment.

These diagrams illustrate the circuit component 10. FIG. 5A is a plan view. FIG. 5B is a cross-sectional view taken along the line B1-B2 in FIG. 5A. FIG. 5C is a cross-sectional view taken along the line B3-B4 in FIG. 5A.

As shown in FIG. 5A, the circuit member 10c of the circuit component 10 includes a circuit layer 10L. The circuit layer 10L includes a first circuit layer portion 10A and a second circuit layer portion 10B. Josephson junctions (such as a first Josephson junction J1 and a second Josephson junction J2) are provided between the first circuit layer portion 10A and the second circuit layer portion 10B.

In the first Josephson junction J1, a first insulating member 16a is provided between a first portion p1 of the first circuit layer portion 10A and a first opposing portion q1 of the second circuit layer portion 10B. In the second Josephson junction J2, a second insulating member 16b is provided between a second portion p2 of the first circuit layer portion 10A and a second opposing portion q2 of the second circuit layer portion 10B. For example, the first circuit layer portion 10A and the second circuit layer portion 10B include a superconducting material.

The first Josephson junction J1 and the second Josephson junction J2 may function, for example, as part of a quantum bit. A high-frequency signal may be supplied to such a circuit component 10. The high-frequency signal may control a magnetic flux passing through a loop 10P including the first Josephson junction J1 and the second Josephson junction J2. Thereby, a calculation based on the quantum bit may be performed.

Thus, the circuit member 10c according to the embodiment may include a Josephson junction. The circuit member 10c may include a superconducting material. The circuit member 10c may include a coplanar circuit.

In the embodiment, the circuit member 10c may include any high frequency circuit based on normal conductor.

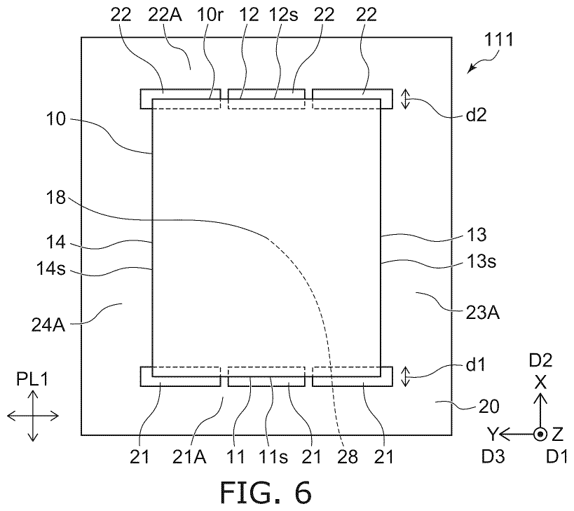

FIG. 6 is a schematic plan view illustrating an electronic circuit according to the first embodiment.

As shown in FIG. 6, in an electronic circuit 111 according to the embodiment, the conductive component 20 includes a plurality of first conductive regions 21 and a plurality of second conductive regions 22. Except for this, the configuration of the electronic circuit 111 may be similar to the configuration of the electronic circuit 110.

In the electronic circuit 111, a direction from one of the plurality of first conductive regions 21 to another one of the plurality of first conductive regions 21 is along the first plane PL1 and crosses the second direction D2. A direction from one of the plurality of second conductive regions 22 to another one of the plurality of second conductive regions 22 is along the first plane PL1 and crosses the second direction D2. The direction from one of the plurality of first conductive regions 21 to another one of the plurality of first conductive regions 21 may be, for example, the third direction D3 (for example, the Y-axis direction). The direction from one of the plurality of second conductive regions 22 to another one of the plurality of second conductive regions 22 may be, for example, the third direction D3 (for example, the Y-axis direction).

The influence of spurious modes can also be suppressed in the electronic circuit 111. Effective heat dissipation can be obtained. An electronic circuit capable of obtaining stable characteristics is provided. The number of the plurality of first conductive regions 21 is arbitrary. The number of the plurality of second conductive regions 22 is arbitrary.

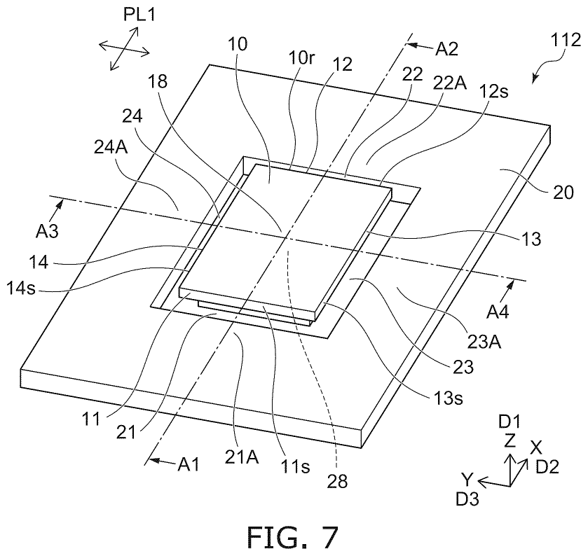

FIG. 7 is a schematic perspective view illustrating an electronic circuit according to the first embodiment.

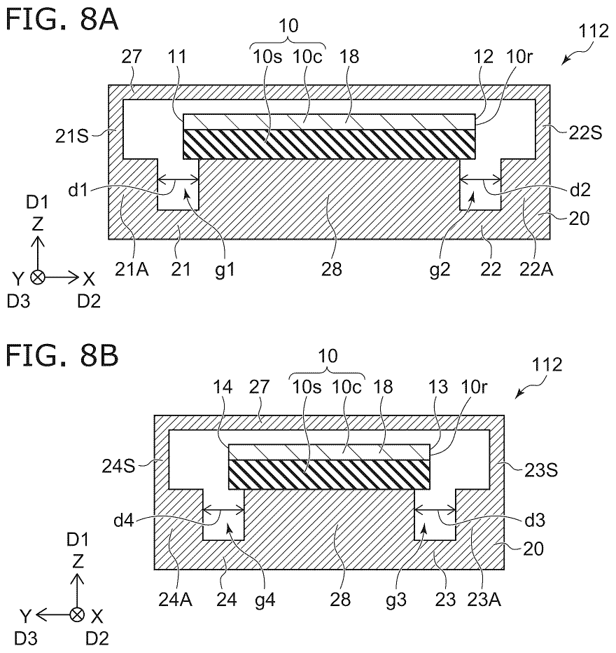

FIGS. 8A and 8B are schematic cross-sectional views illustrating the electronic circuit according to the first embodiment.

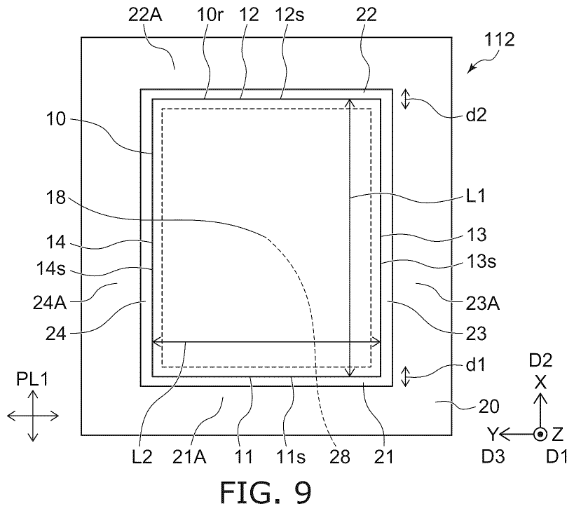

FIG. 9 is a schematic plan view illustrating the electronic circuit according to the first embodiment.

FIG. 8A is a cross-sectional view taken along the line A1-A2 in FIG. 7. FIG. 8B is a cross-sectional view taken along the line A3-A4 in FIG. 7.

As shown in FIGS. 7 and 8B, in an electronic circuit 112 according to the embodiment, the conductive component 20 further includes a third conductive region 23 and a fourth conductive region 24. Except for this, the configuration of the electronic circuit 112 may be the same as the configuration of the electronic circuit 110. A part of components (such as the opposing conductive region 27) are omitted in FIGS. 7 and 9.

In the electronic circuit 112, the outer edge 10r of the circuit component 10 includes a third partial region 13 and a fourth partial region 14. The third direction D3 from the third partial region 13 to the fourth partial region 14 is along the first plane PL1 and crosses the second direction D2. The third direction D3 may be, for example, the Y-axis direction.

As shown in FIGS. 7 and 8B, a position of the inner conductive region 28 in the third direction D3 is between a position of the third conductive region 23 in the third direction D3 and a position of the fourth conductive region 24 in the third direction D3.

As shown in FIG. 8B, a third gap g3 exists between the third conductive region 23 and the third partial region 13. A fourth gap g4 exists between the fourth conductive region 24 and the fourth partial region 14. In the electronic circuit 112, in addition to suppressing the effects of spurious modes in the second direction D2, the effects of spurious modes in the third direction D3 are also suppressed. Effective heat dissipation is also achieved in the electronic circuit 112. An electronic circuit capable of achieving stable characteristics is provided.

As shown in FIG. 8B, the inner conductive region 28 protrudes toward the circuit component 10 with respect to the third conductive region 23 and the fourth conductive region 24. The third conductive region 23 and the fourth conductive region 24 recede with respect to the inner conductive region 28.

As already described, the conductive component 20 may further include the third outer conductive region 23A and the fourth outer conductive region 24A. The position of the third conductive region 23 in the third direction D3 is between the position of the inner conductive region 28 in the third direction D3 and the position of the third outer conductive region 23A in the third direction D3. The position of the fourth conductive region 24 in the third direction D3 is between the position of the inner conductive region 28 in the third direction D3 and the position of the fourth outer conductive region 24A in the third direction D3. The third gap g3 exists between the inner conductive region 28 and the third outer conductive region 23A. The fourth gap g4 exists between the inner conductive region 28 and the fourth outer conductive region 24A.

For example, the third conductive region 23 and the fourth conductive region 24 correspond to a recess. For example, the third conductive region 23 and the fourth conductive region 24 may be a hole or a groove. The inner conductive region 28 corresponds to, for example, a protrusion.

The recess based on the third conductive region 23 may be continuous with the recess based on the first conductive region 21. The recess based on the third conductive region 23 may be continuous with the recess based on the second conductive region 22. The recess based on the fourth conductive region 24 may be continuous with the recess based on the first conductive region 21. The recess based on the fourth conductive region 24 may be continuous with the recess based on the second conductive region 22.

In the example of the electronic circuit 112, the third conductive region 23 overlaps the entire third partial region 13 in the first direction D1. The fourth conductive region 24 overlaps the entire fourth partial region 14 in the first direction D1.

In the embodiment, the third conductive region 23 may overlap a part of the third partial region 13 in the first direction D1. The fourth conductive region 24 may overlap a part of the fourth partial region 14 in the first direction D1.

In the embodiment, a plurality of third conductive regions 23 may be provided. A plurality of fourth conductive regions 24 may be provided. In the electronic circuit 112, the first length L1 may be longer than, shorter than, or the same as the second length L2.

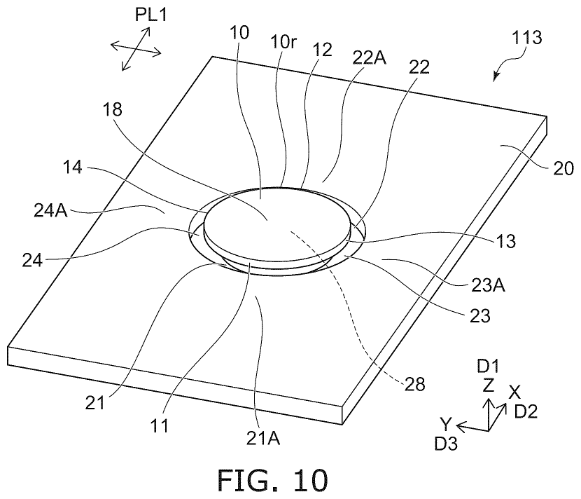

FIG. 10 is a schematic perspective view illustrating an electronic circuit according to the first embodiment.

As shown in FIG. 10, in an electronic circuit 113 according to the embodiment, at least a part of the outer edge 10r of the circuit component 10 is curved. Except for this, the configuration of the electronic circuit 113 may be the same as the configuration of the electronic circuit 112, etc.

As in the example of electronic circuit 113, at least a part of the first partial region 11 may be curved. At least a part of the second partial region 12 may be curved. At least a part of the third partial region 13 may be curved. At least a part of the fourth partial region 14 may be curved. In the electronic circuit 113 as well, the effects of spurious modes are suppressed. Effective heat dissipation is obtained. An electronic circuit capable of obtaining stable characteristics is provided.

As in the example of the electronic circuit 113, the first conductive region 21 (e.g., a groove) may be curved along the curve of the first partial region 11. The second conductive region 22 (e.g., a groove) may be curved along the curve of the second partial region 12. The third conductive region 23 (e.g., a groove) may be curved along the curve of the third partial region 13. The fourth conductive region 24 (e.g., a groove) may be curved along the curve of the fourth partial region 14.

The outer edge 10r may be, for example, circular or flattened circular. The grooves based on the conductive regions may be, for example, circular or flattened circular.

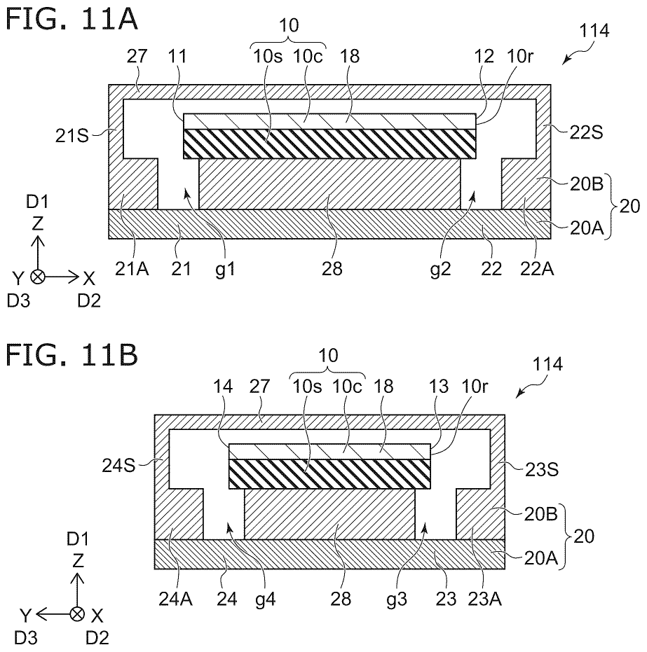

FIGS. 11A and 11B are schematic cross-sectional views illustrating an electronic circuit according to the first embodiment.

As shown in FIGS. 11A and 11B, in an electronic circuit 114 according to the embodiment, the conductive component 20 include a first conductive component 20A and a second conductive component 20B. Except for this, the configuration of the electronic circuit 114 may be the same as the configuration of the electronic circuit 113, etc.

For example, the first conductive region 21 and the second conductive region 22 are included in the first conductive component 20A. For example, the inner conductive region 28 is included in the second conductive component 20B. The inner conductive region 28 is between a part of the first conductive component 20A and the circuit component 10. The boundary between the first conductive component 20A and the second conductive component 20B may be clear or unclear. The material of the first conductive component 20A may be the same as or different from the material of the second conductive component 20B.

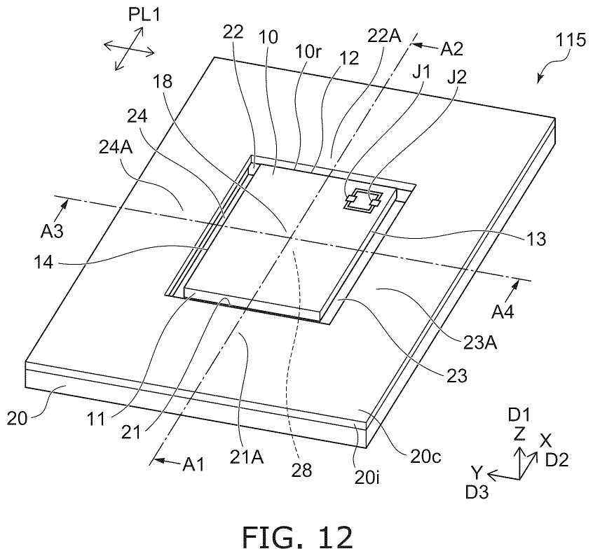

FIG. 12 is a schematic perspective view illustrating an electronic circuit according to the first embodiment.

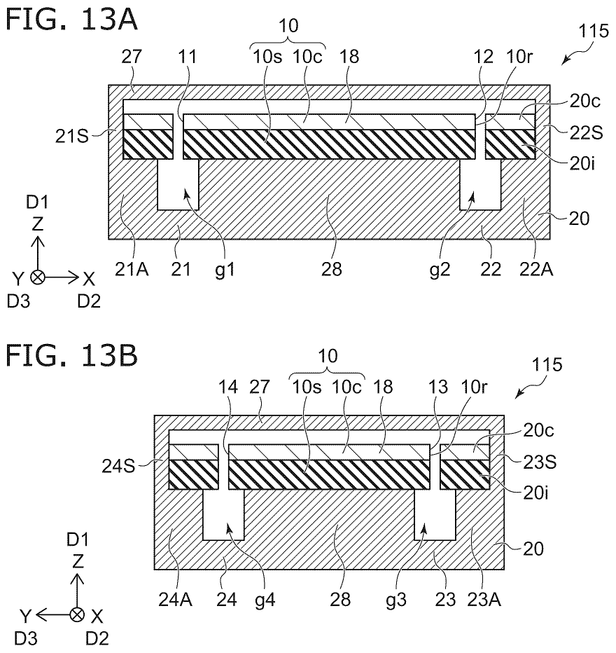

FIGS. 13A and 13B are schematic cross-sectional views illustrating the electronic circuit according to the first embodiment.

FIG. 13A is a cross-sectional view taken along the line A1-A2 in FIG. 12. FIG. 13B is a cross-sectional view taken along the line A3-A4 in FIG. 12.

As shown in FIGS. 12, 13A and 13B, an electronic circuit 115 according to the embodiment further includes a conductive layer 20c. In this example, the electronic circuit 115 includes an insulating layer 20i. Except for this, the configuration of the electronic circuit 115 may be the same as the configuration of the electronic circuit 112 etc. In FIG. 12, a part of the components (such as the opposing conductive region 27) are omitted.

In the electronic circuit 115, the insulating layer 20i is provided between the outer conductive regions (first outer conductive region 21A, second outer conductive region 22A, third outer conductive region 23A, and fourth outer conductive region 24A) and the conductive layer 20c. The member including the conductive layer 20c and the insulating layer 20i may be, for example, a PCB (printed circuit board). At least a part of the conductive layer 20c may be, for example, a connection layer.

Various signals may be supplied to the conductive layer 20c from the outside. The signals supplied to the conductive layer 20c may be supplied to the circuit component 10. A signal obtained from the circuit component 10 may be supplied to the conductive layer 20c. The signals supplied to the conductive layer 20c may be output to the outside.

A part of the conductive member included in the circuit member 10c may be coupled to a conductive member included in the conductive layer 20c. The coupling may include electromagnetic coupling such as capacitive coupling. The coupling may include electrical connection.

### Second Embodiment

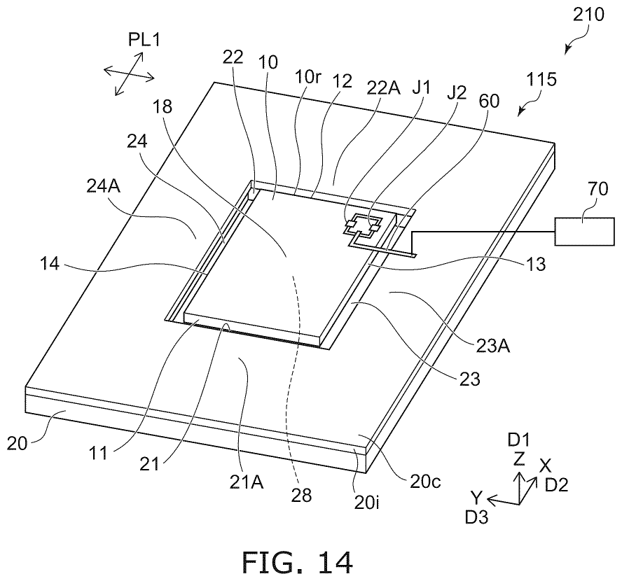

FIG. 14 is a schematic perspective view illustrating a computing device according to a second embodiment.

As shown in FIG. 14, a computing device 210 includes an arbitral electronic circuit according to the first embodiment (in this example, the electronic circuit 115), a control conductive member 60, and a controller 70. The controller 70 is configured to supply a signal to the control conductive member 60.

A magnetic field corresponding to the signal supplied to the control conductive member 60 is applied from the control conductive member 60 to the circuit component 10. For example, the magnetic flux passing through a loop 10P (see FIG. 5A) including the first Josephson junction J1 and the second Josephson junction J2 is controlled. A calculation may be performed using quantum bits. The computing device 210 may be, for example, a quantum computer.

The electronic circuit 115 included in the computing device 210 may include the conductive layer 20c. The conductive layer 20c may be configured to be coupled to the control conductive member 60. The signal provided from the controller 70 may be provided to the control conductive member 60 via the conductive layer 20c. The coupling may include electromagnetic coupling, such as capacitive coupling. The coupling may include electrical connection.

The embodiments may include the following Technical proposals:

### (Technical Proposal 1)

An electronic circuit, comprising:
a circuit component including a dielectric substrate and a circuit member, the circuit component includes an outer edge and an inner region inside the outer edge on a first plane crossing a first direction from the dielectric substrate to the circuit member, the outer edge including a first partial region and a second partial region, the inner region being between the first partial region and the second partial region in a second direction crossing the first direction along the first plane; and
a conductive component including an inner conductive region, a first conductive region, and a second conductive region, a position of the inner conductive region in the second direction being between a position of the first conductive region in the second direction and a position of the second conductive region in the second direction, a direction from the inner conductive region to the inner region being along the first direction, a first gap being between the first conductive region and the first partial region, and a second gap being between the second conductive region and the second partial region.

### (Technical Proposal 2)

The electronic circuit according to Technical proposal 1, wherein
the inner conductive region supports the inner region.

### (Technical Proposal 3)

The electronic circuit according to Technical proposal 1, wherein

The inner conductive region is in contact with the inner region.

### (Technical Proposal 4)

The electronic circuit according to any one of Technical proposals 1-3, wherein
the inner conductive region protrudes toward the circuit component with respect to the first conductive region and the second conductive region.

### (Technical Proposal 5)

The electronic circuit according to any one of Technical proposals 1-4, wherein
the conductive component further includes a first outer conductive region and a second outer conductive region,
the position of the first conductive region in the second direction is between the position of the inner conductive region in the second direction and a position of the first outer conductive region in the second direction,
the position of the second conductive region in the second direction is between the position of the inner conductive region in the second direction and a position of the second outer conductive region in the second direction,
the first gap is between the inner conductive region and the first outer conductive region, and
the second gap is between the inner conductive region and the second outer conductive region.

### (Technical Proposal 6)

The electronic circuit according to Technical proposal 5, wherein
a ratio of a first distance in the second direction between the inner conductive region and the first outer conductive region to a first length in the second direction of the circuit component is 0.1 or more.

### (Technical Proposal 7)

The electronic circuit according to Technical proposal 5, wherein
a ratio of a first distance in the second direction between the inner conductive region and the first outer conductive region to a first length in the second direction of the circuit component is 0.3 or less.

### (Technical Proposal 8)

The electronic circuit according to any one of Technical proposals 1-7, wherein
a first length of the circuit component in the second direction is longer than a second length of the circuit component in a crossing direction, and
the crossing direction is along the first plane and crosses the second direction.

### (Technical Proposal 9)

The electronic circuit according to any one of Technical proposals 1-8, wherein
the conductive component further includes an opposing conductive region, and
the circuit component is between the inner conductive region and the opposing conductive region in the first direction.

### (Technical Proposal 10)

The electronic circuit according to any one of Technical proposals 1-9, wherein
the first partial region includes at least a part of a first side of the outer edge, and
the second partial region includes at least a part of a second side of the outer edge.

### (Technical Proposal 11)

The electronic circuit according to any one of Technical proposals 1-10, wherein
at least a part of the first partial region is curved.

### (Technical Proposal 12)

The electronic circuit according to any one of Technical proposals 1-11, wherein
the conductive component includes a plurality of the first conductive regions and a plurality of the second conductive regions,
a direction from one of the plurality of first conductive regions to another one of the plurality of first conductive regions is along the first plane and crosses the second direction;
a direction from one of the plurality of second conductive regions to another one of the plurality of second conductive regions is along the first plane and crosses the second direction.

### (Technical Proposal 13)

The electronic circuit according to any one of Technical proposals 1-11, wherein
the first conductive region overlaps the entire first partial region in the first direction, and
the second conductive region overlaps the entire second partial region in the first direction.

### (Technical Proposal 14)

The electronic circuit according to any one of Technical proposals 1-13, wherein
the outer edge further includes a third partial region and a fourth partial region,
a third direction from the third partial region to the fourth partial region is along the first plane and crosses the second direction,
the conductive component further includes a third conductive region and a fourth conductive region,
a position of the inner conductive region in the third direction is between a position of the third conductive region in the third direction and a position of the fourth conductive region in the third direction,
a third gap is between the third conductive region and the third partial region, and
a fourth gap is between the fourth conductive region and the fourth partial region.

### (Technical Proposal 15)

The electronic circuit according to Technical proposal 14, wherein
the third conductive region overlaps the entire third partial region in the first direction, and
the fourth conductive region overlaps the entire fourth partial region in the first direction.

### (Technical Proposal 16)

The electronic circuit according to any one of Technical proposals 1-15, wherein
the circuit member includes a Josephson junction.

### (Technical Proposal 17)

The electronic circuit according to Technical proposal 16, wherein
the circuit member includes a superconducting material.

### (Technical Proposal 18)

The electronic circuit according to Technical proposal 17, wherein
the circuit member includes a coplanar circuit.

### (Technical Proposal 19)

A computing device, comprising:
the electronic circuit according to any one of Technical proposals 16-18; and
a control conductive member; and
a controller configured to provide a signal to the control conductive member.

### (Technical Proposal 20)

The computing device according to Technical proposal 19, further comprising:
a conductive layer configured to couple to the control conductive member.

According to the embodiment, an electronic circuit and a computing device can be provided that can obtain stable characteristics.

In the present specification, the term “electrical connection” includes a state in which a plurality of conductors are physically in contact and a current flows between the plurality of conductors. The “electrical connection” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the electronic circuits and the computing devices, such as circuit components, dielectric substrates, circuit members, conductive components, conductive regions, control conductive members, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electronic circuits and all computing devices practicable by an appropriate design modification by one skilled in the art based on the electronic circuits and the computing devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic circuit, comprising:
a circuit component including a dielectric substrate and a circuit member, the circuit component includes an outer edge and an inner region inside the outer edge on a first plane crossing a first direction from the dielectric substrate to the circuit member, the outer edge including a first partial region and a second partial region, the inner region being between the first partial region and the second partial region in a second direction crossing the first direction along the first plane; and
a conductive component including an inner conductive region, a first conductive region, and a second conductive region, a position of the inner conductive region in the second direction being between a position of the first conductive region in the second direction and a position of the second conductive region in the second direction, a direction from the inner conductive region to the inner region being along the first direction, a first gap being between the first conductive region and the first partial region, and a second gap being between the second conductive region and the second partial region.

2. The electronic circuit according to claim 1, wherein
the inner conductive region supports the inner region.

3. The electronic circuit according to claim 1, wherein
The inner conductive region is in contact with the inner region.

4. The electronic circuit according to claim 1, wherein
the inner conductive region protrudes toward the circuit component with respect to the first conductive region and the second conductive region.

5. The electronic circuit according to claim 1, wherein
the conductive component further includes a first outer conductive region and a second outer conductive region,
the position of the first conductive region in the second direction is between the position of the inner conductive region in the second direction and a position of the first outer conductive region in the second direction,
the position of the second conductive region in the second direction is between the position of the inner conductive region in the second direction and a position of the second outer conductive region in the second direction,
the first gap is between the inner conductive region and the first outer conductive region, and
the second gap is between the inner conductive region and the second outer conductive region.

6. The electronic circuit according to claim 5, wherein
a ratio of a first distance in the second direction between the inner conductive region and the first outer conductive region to a first length in the second direction of the circuit component is 0.1 or more.

7. The electronic circuit according to claim 5, wherein
a ratio of a first distance in the second direction between the inner conductive region and the first outer conductive region to a first length in the second direction of the circuit component is 0.3 or less.

8. The electronic circuit according to claim 1, wherein
a first length of the circuit component in the second direction is longer than a second length of the circuit component in a crossing direction, and
the crossing direction is along the first plane and crosses the second direction.

9. The electronic circuit according to claim 1, wherein
the conductive component further includes an opposing conductive region, and
the circuit component is between the inner conductive region and the opposing conductive region in the first direction.

10. The electronic circuit according to claim 1, wherein
the first partial region includes at least a part of a first side of the outer edge, and
the second partial region includes at least a part of a second side of the outer edge.

11. The electronic circuit according to claim 1, wherein
at least a part of the first partial region is curved.

12. The electronic circuit according to claim 1, wherein
the conductive component includes a plurality of the first conductive regions and a plurality of the second conductive regions,
a direction from one of the plurality of first conductive regions to another one of the plurality of first conductive regions is along the first plane and crosses the second direction;
a direction from one of the plurality of second conductive regions to another one of the plurality of second conductive regions is along the first plane and crosses the second direction.

13. The electronic circuit according to claim 1, wherein
the first conductive region overlaps the entire first partial region in the first direction, and
the second conductive region overlaps the entire second partial region in the first direction.

14. The electronic circuit according to claim 1, wherein
the outer edge further includes a third partial region and a fourth partial region,
a third direction from the third partial region to the fourth partial region is along the first plane and crosses the second direction,
the conductive component further includes a third conductive region and a fourth conductive region,
a position of the inner conductive region in the third direction is between a position of the third conductive region in the third direction and a position of the fourth conductive region in the third direction,
a third gap is between the third conductive region and the third partial region, and
a fourth gap is between the fourth conductive region and the fourth partial region.

15. The electronic circuit according to claim 14, wherein
the third conductive region overlaps the entire third partial region in the first direction, and
the fourth conductive region overlaps the entire fourth partial region in the first direction.

16. The electronic circuit according to claim 1, wherein
the circuit member includes a Josephson junction.

17. The electronic circuit according to claim 16, wherein
the circuit member includes a superconducting material.

18. The electronic circuit according to claim 17, wherein
the circuit member includes a coplanar circuit.

19. A computing device, comprising:
the electronic circuit according to claim 16; and
a control conductive member; and
a controller configured to provide a signal to the control conductive member.

20. The computing device according to claim 19, further comprising:
a conductive layer configured to couple to the control conductive member.
